(19) United States
(12) Patent Application Publication
(10) Pub. No.: US 2010/0224913 A1
(43) Pub. Date: Sep. 9, 2010

(54) One-dimensional FET-based corrosion sensor and method of making same

(75) Inventors: Kuang-Tsan Kenneth Chiang, Helotes, TX (US); Bruce Roy Lanning, Littleton, CO (US)

Correspondence Address: Navarro Law Office, PC, PO Box 166851, Irving, TX, 75016, US

(73) Assignee: Southwest Research Institute, San Antonio, TX (US)

(21) Appl. No.: 12/380,752

(22) Filed: Mar. 3, 2009

(51) Int. Cl. H01L 29/66; H01L 21/28

(52) U.S. Cl. 257/253; 438/49; 257/E29.166; 257/E21.158

(57) ABSTRACT

A field effect transistor corrosion sensor (10) comprises a doped silicon-on-insulator chip layer (14) and nanostructured channels (16) developed on the chip layer (14). A nafion receptive or sensor layer (30) is developed over the nanostructured channels (16). The sensor (10) includes source (24) and drain electrodes (22) attached to the ends (20, 18) of the channels (16) for signal conductivity between the electrodes (22, 24) via the nanostructured channels (16). A protective coating layer (54) is developed over the channels (16) and has an opening (56) which allows some portion of said Nafion receptive layer (30) to remain exposed to the environment.

### TECHNICAL FIELD

The present invention relates to small devices for use in detecting environmental parameters of interest. More particularly, the invention relates to the use of nanoscale fabrication techniques to allow the manufacture of a field effect transistor based corrosion sensor. Still more particularly, the invention relates to a one-dimensional field effect transistor sensor and a related method of manufacture that employ a nafion-receptive layer to enable detection of a condition leading to corrosion.

### BACKGROUND OF THE INVENTION

In-situ monitoring of corrosion and other environmental conditions has become increasingly important in recent years. One critical application involves the disposal and storage of nuclear waste material. In developing a suitable nuclear waste repository system one must be able to monitor the environmental parameters leading to corrosion that may compromise the integrity of the waste package container. Due to moisture in the air and flowing groundwater, an aqueous solution may be formed in contact with the waste package container that may cause degradation by corrosion and a potential release of radionuclides from the container and/or contamination of the groundwater.

In addition, as the waste repository will experience a high-temperature drying out period and the waste packages are practically inaccessible after emplacement, monitoring requires a long lasting, maintenance-free, high-temperature resistant and highly robust remote sensor. Because the corrosion rate of the waste package container material is low, a suitable sensor for this application must also be highly sensitive.

Prior art sensor for such applications focused on the measurement of pH only. See Dietz, T. and K. G. Kreider. “Review of Materials for pH Sensing for Nuclear Waste Containment.” Washington, D.C.: National Institute of Standard and Technology, NBSIR 85-3237. 1985. Additionally, the size of such prior art sensors was on the order of 10 to 100-mm range which made them difficult to integrate onto small substrates. Reducing the sensor size to 10-100 μm (10⁻⁶ m) would make the devices more compact and allow the development of atmospheric corrosion sensors that would not only monitor and measure the corrosion rate continuously, but measure the corrosion-causing atmospheric parameters as well.

Therefore, a reduced sensor capable of detecting an environmental parameter of interest, such as a condition leading to corrosion, would provide numerous advantages.

### BRIEF DESCRIPTIONS OF THE DRAWINGS

The present invention is illustrated by way of example and not limitation in the figures of the accompanying drawings in which like references indicate similar elements, and in which:

FIGS. 1a and 1b illustrate a one dimensional field effect transistor sensor according to the invention;

FIG. 2 shows a one dimensional field effect transistor sensor in layer by layer format according to the invention;

FIG. 3 is a process flow diagram of a method for making a one dimension field effect transistor sensor according to the invention;

FIG. 4 is a process flow diagram showing the steps of fabricating nanostructured channels on a field effect transistor sensor according to the invention;

FIG. 5 is a process flow diagram showing the steps of fabricating the ohmic contacts and conducting traces on a field effect transistor sensor according to the invention; and

FIG. 6 shows various response curves illustrating the current versus source-to-drain voltage performance of a field effect transistor sensor using a Nafion sensitivity layer to detect relative humidity levels, a parameter indicative of corrosion.

### DETAILED DESCRIPTION

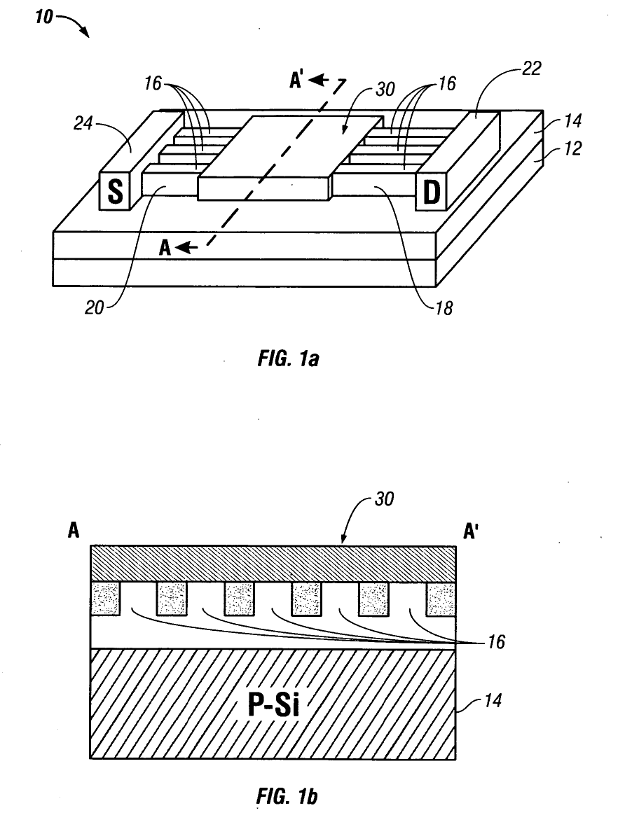

Referring first to FIG. 1a, a perspective view of a one dimensional field effect transistor sensor according to the invention is shown and denoted generally as 10. Sensor 10 includes a frame or frame chip 12 supporting a silicon layer 14 which may be formed using scalable semiconductor processing techniques well known in the art. In one embodiment, frame 12 and layer 14 are approximately 1 cm by 1 cm in chip size to allow system level integration using known methods. Layer 14 may be fabricated using a boron-doped, p-type silicon-on-insulator material using advanced semiconductor processing techniques such as those described by S. Wolf and R. N. Tauber in “Silicon Processing for the VLSI Era”, Volume 1—Process Technology, Lattice Press, Sunset Beach, Calif. 1986.

Still referring to FIG. 1a, sensor 10 is also shown to include a plurality of nanostructured channels 16 which may be developed on layer 14 using standard semiconductor processing techniques. Each of the channels 16 extend across most of the layer 14 and have a first end 18 and a second end 20 to which corresponding electrodes 22 and 24, respectively, are conductively attached. Drain electrode 22 and source electrode 24 may comprise the source and drain electrodes of standard field effect transistor device.

As shown in FIGS. 1a and 1b, a sensor layer 30 has been formed over a portion of channels 16. As described herein, sensor layer 30 is made of a material reactive to at least one environmental parameter of interest. The fact that sensor layer 30 is capable of reacting to at least one environmental parameter of interest allows sensor 10 to be used for detecting environment conditions, such as a condition leading to corrosion.

FIG. 1b shows a cross-section of sensor 10 along line A-A′. In general, it has been discovered that using a plurality of channels 16 increased the surface-to-volume ratio of the sensor 10 resulting in detection sensitivity. While sensor 10 is shown to include 6 channels 16, it should be understood that the number of channels may vary according to various embodiments and applications. Development and fabrication of the channels 16 in silicon may be achieved using combined Electron Beam Lithography (EBL) and ion milling/reactive ion etching techniques, as described more fully below. An amorphous SiO₂ (aSiO₂) insulating layer may be thermally formed on channel features and the substrate surface.

A micron-scale template, with an array of addressable traces, may be constructed using standard lithographic methods. Feature size and/or line trace widths and spacings may be set using high resolution capabilities of ITN Energy Systems, Inc. or another similar vendor. These micron-scale traces may be fed into individual contact pads of the sensor elements (i.e., the drain and source electrodes 22 and 24, respectively). Additionally, it is possible to prepare multiple elements on a single e-beam write field with each element containing variations in channel geometry and number and having variations in channel height-to-width ratio, channel width, and channel spacing. Nominal channel width and spacing of the channels 16 may be on the order of 10 and 50 nm, respectively. Other design variables may include the number of channels, channel length, channel width, and channel spacing.

In one embodiment a field effect transistor sensor, such as sensor 10, is produced having 12 separate device designs, 6 devices having 5-channels and the other 6 have 10-channels where the channel lengths (L) were 0.8 or 2 μm. The channel widths (W) may typically range from 40 nm (0.04 μm) to 80 nm (0.08 μm), with the individual channel area can be calculated from Equation 1:

A(μm)=L(μm)×W(μm) Equ. 1

As would be appreciated by one of ordinary skill, fabrication of one-dimensional channels 16 may be carried out using a thin layer of photo resist applied to the frame chip 12, and an EBL nano-pattern mask. Features of the channels 16 may then be transferred onto a substrate and ion milled through to a substrate SiO₂ insulator layer. In one embodiment, 12 devices are fabricated on a 1 cm×1 cm substrate. Channels 16 may be trapezoidal in shape and the channels 16 for each device may vary in number, width (50-100 nm is typical), length (0.8-2 μm is typical) and spacing (100-200 nm is typical) so that performance of the sensor 10 can be optimized depending on the application and through testing and characterization.

Thus, in general, a process for fabricating a field effect transistor sensor, such as sensor 10, may comprise the following process steps:

1. Ion-milling frame chips to nominal doped silicon thickness.

2. EBL computer-aided design (CAD) pattern and run file generation.

3. Spin polymethyl methacrylate (PMMA) resist and bake.

4. EBL channel patterning.

5. Development of EBL channel patterns.

6. Ion milling of the FET channels.

7. Liftoff of remaining resist and plasma clean.

8. Scanning electron microscopy (SEM) imaging.

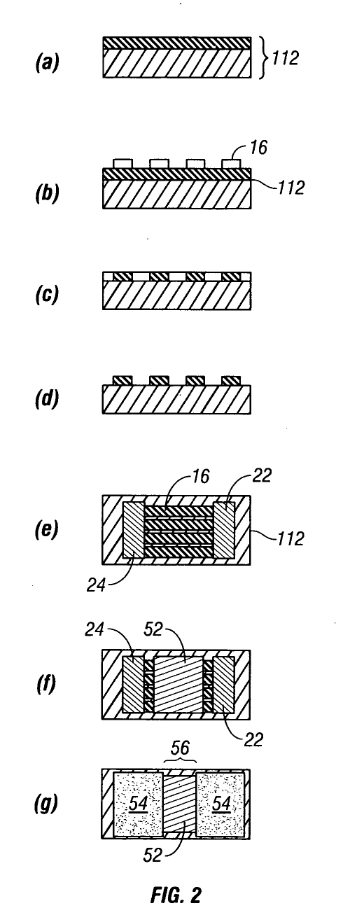

Referring to FIG. 2, the development of a one dimensional field effect transistor corrosion sensor 50 according to the invention is illustrated. In FIG. 2(a), a doped silicon-on-insulator chip layer 112 is processed by the use of EBL to pattern out channels 16. Channels 16 can be developed by application of a resist polymethyl methacrylate and standard fabrication techniques, FIG. 2(b). Next, sensor 50 is subjected to a reactive ion etching step, FIG. 2(c), and thermal oxidation FIG. 2(d). In FIG. 2(e), electrodes 22 and 24 are formed utilizing standard fabrication techniques and a sensitivity layer 52 is formed over the structure, FIG. 2(f). A protective coating 54 is added, FIG. 2(e), over the chip layer 12, channels 16 and sensitivity layer 52 such that an opening 56 allows some portion of the sensitivity layer 52 to remain exposed to the environment.

### Determination of Ion Milling Rate

In one embodiment, the SOI chip layer 112 thickness is milled down to a nominal thickness of 500 Å (50 nm). This may be accomplished by milling a pattern into the chip layer 112 and the resultant cavity measured with a profilometer to determine the mill rate. It has been found that a mill rate of 35 Å/minute is suitable for one environment. To determine whether the ion milling has in fact removed the doped silicon material through to the oxide layer, it is possible to include witness chips along with the EBL chips with the channel patterns during the milling procedure. The oxide layer may be measured with the nano-optical microscope for film thickness characterization using a known SiO₂ chip as a source of reference. A profilometer measurement may also be made as a second source of thickness verification.

### Selection of E-Beam Resist

ITN Energy Systems, Inc. routinely uses two different kinds of e-beam resist for lithography: polymethyl methacrylate (PMMA) and polymethylglutarimide (PMGI). As is known, PMMA is the classical e-beam resist and offers the advantage of extremely high resolution, ease of handling, and ready availability [Thompson et al., 1994]. PMGI is a variation of PMMA. PMGI has a slower mill rate that might be useful in some circumstances although both may be utilized as would be understood by those of ordinary skill. It has been found, however, that PMMA is sufficient to create a nominal channel device thickness of 50 nm.

### Characterization of Channels 16 Using Atomic Force Microscopy

In general, due to the size of the channels 16 and the characteristics (i.e., conductivity) of the surrounding material, it may be difficult to image the channels 16 with SEM. It has been found that atomic force microscopy (AFM) may be used to image the channels 16. In that regard, AFM may as operated in the contact mode with a scan rate of 0.90 Hz. Prior to imaging, the AFM may be calibrated with a specimen of 3 μm×3 μm×142 nm having known features.

In one embodiment, 12 trenches may be imaged by AFM, first at a magnification of 10×10 μm, followed by a scan at a higher magnification of 5×5 μm. The low magnification images may show the trenches as being approximately 4 μm wide, with a series of ridges or lines in the approximate center of each trench.

### Formation of Ohmic Contact

The next step for one dimensional device fabrication was the formation of ohmic contacts and the formation of conducting traces to macropads. Formation of ohmic contacts on the one dimensional channel may be accomplished in two EBL steps. A pad may first be patterned for the ohmic contact. Once resist for the pad is applied and patterned, the surface may be cleaned to expose an active silicon channel and then coated with a 25 Å Ti/500 Å Au contact layer. The process may be followed by a 300-600° C. postheat treatment in forming gas (H₂/Ar) for approximately 1 hour to form the ohmic junction. A contact pad lithography CAD pattern 2 may then be generated.

Formation of Conductive Traces from One Dimensional Channels

Procedures for producing a conductive trace from the nanometer-scale FET devices to the micronscale contact pad may be employed using known techniques. The processes involved conventional photolithography using a resist-spin and bake technique and exposure through an optical mask.

An additional process step may be required to form conductive traces from the one dimensional channels 16. Because of the difficulty in aligning the conductive traces to the Ti/AI contact pad, an EBL process may be used to deposit Ti/Au traces connecting the Ti/AI contact pad to the edge of the e-beam write field.

### Formation of Conductive Traces to Micron-Scale Contact Pad

The patterning process typically also includes the formation of conductive traces from the e-beam write field edge to a micron-scale contact pad using standard optical lithography. For a regular silicon chip, an exposure time of 70 seconds may be used. For an ion milled SOI chip, such as chip layer 112, it was found less than half of the exposure time was needed. A completed one dimensional field effect transistor device, such as sensor 10 or sensor 50, with ohmic contacts and conductive traces may be verified using AFM.

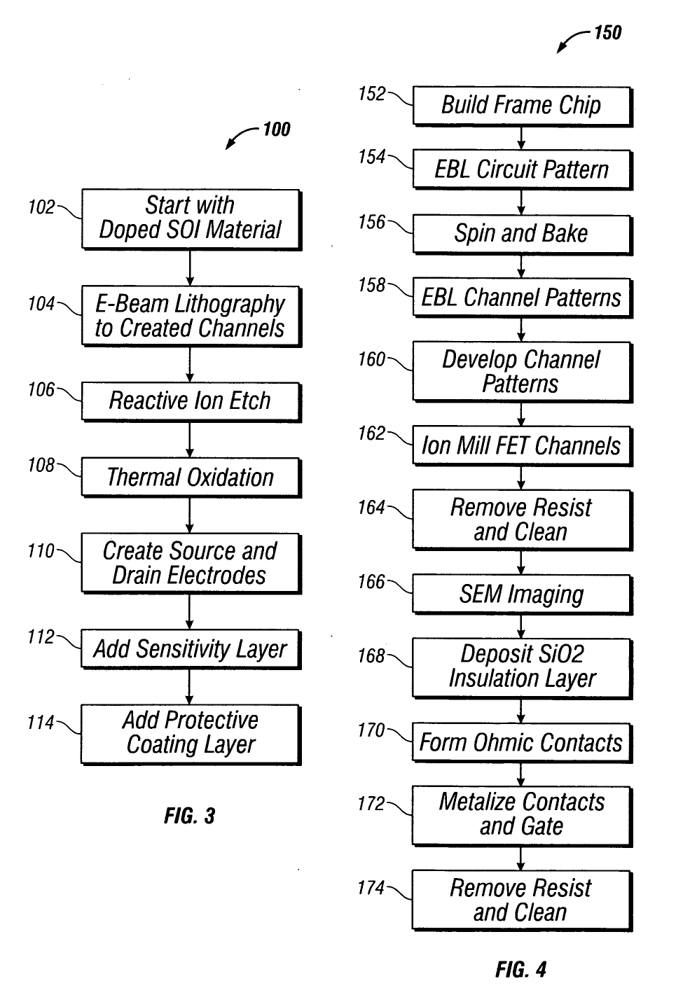

Referring to FIG. 3, a process flow diagram for method of fabricating a field effect transistor corrosion sensor according to the invention is shown and generally denoted as 100. At step 102, the doped SOI material is formed using scalable semiconductor processing techniques to build a suitable chip layer, such as layer 112. Layer 112 may be fabricated using a boron-doped, p-type silicon-on-insulator material which is milled to nominal silicon thickness. Next, at step 104, EBL is utilized to create a plurality of nanostructured channels on the chip layer. A reactive ion etch, step 106, is used to form the conducting traces followed by thermal oxidation, step 108. Next, at step 110, the source and drain electrodes are created followed by addition of a sensitivity layer, step 112 and protective coating layer, step 114.

With reference to FIG. 4, a process flow diagram outlining specific steps involved in the fabrication of a sensor according to the invention is shown and denoted generally as 150. At step 152, the frame chip is formed to provide the sensor base and chip layer. As appreciated by those of ordinary skill, step 152 may involve dicing a silicon wafer, such as a 6″ diameter silicon wafer, to nominal frame chip dimensions (of 1 cm by 1 cm, for example) and milling the frame chip to nominal doped silicon thickness. Next, at step 154, E-beam lithography (EBL) can be used to pattern a computer-aided design on the chip layer and the pattern can then be spun, resist applied (EBL resist polymethyl methacrylate (PMMA)) and baked, step 156.

At step 158, channels can be pattered using EBL and the channel patterns developed, step 160. At step 162 the field effect transistor channels, such as channels 16, are ion milled to form the channel profile and the remaining resist is lifted/removed and cleaned (step 164) using, for example, a plasma cleaning process. At step 166, a scanning electron microscope (SEM) can be used to image the channel and trace patterns and a plasma-enhanced chemical vapor deposition (PECVD) SiO₂ insulation layer (30 nm thick) can then be deposited, step 168.

At step 170, the ohmic contacts to the chip layer and channels are formed. This may involve similar steps to those used to form the nanostructured channels (spin, resist and bake for ohmic contact patterning, EBL patterning of channel ohmic contacts, developing EBL ohmic contact patterns, and milling the SiO₂ material covering the channel features for the ohmic contact areas) as would be appreciated by those of ordinary skill. Next, at step 172, the sensor contacts and gate electrode are metalized by depositing a suitable metal in sufficient quantities, such as 500 Å Ti/500 Å Au, on the frame chip. It has been found that one run for the top side channel ohmic contacts and one run for the bottom side gate contact may be used for this purpose. At step 174, the sensor profile can be cleaned by lifting off any remaining resist and plasma clean.

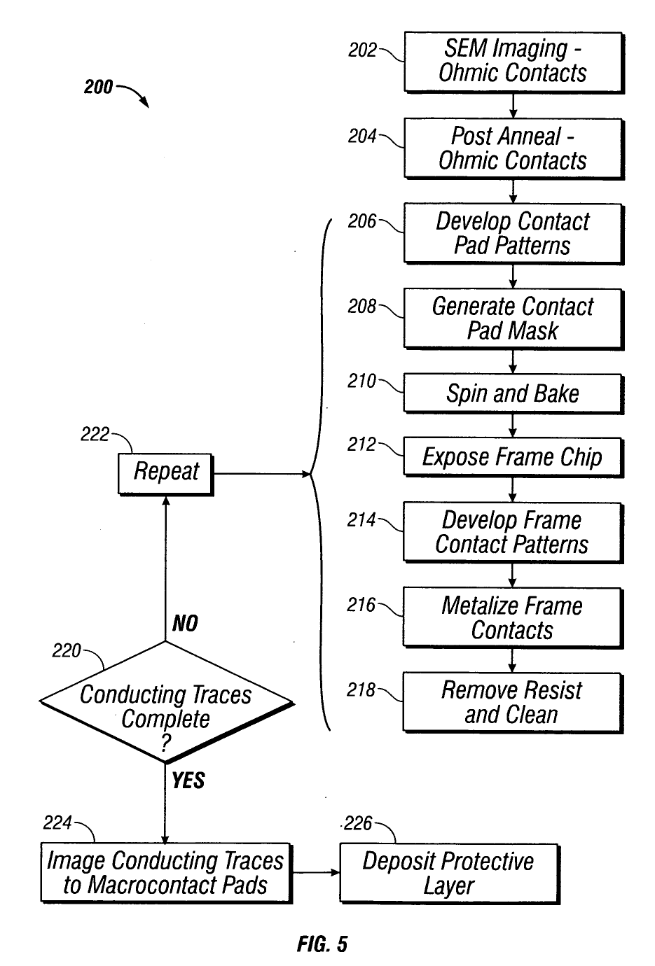

Referring now to FIG. 5, a process flow diagram showing the remaining steps involved in fabricating a sensor according to one specific embodiment is shown and denoted generally as 200. At step 202, the ohmic contacts to the sensor are SEM imaged followed by post anneal, step 204, which may be accomplished by baking at 400° C. in argon/H₂ gas for 5 min.

The contact pad patterns, step 206, may be developed by generating a contact pad mask, step 208, spinning photolithography resist and baking the pattern, step 210. Next, the frame chip is exposed with photolithography contact pad mask, step 212. At step 214, the frame contact patterns may be developed after which, the frame contact pads may be metalized (step 216) by depositing 25 Å Ti/1000 Å Au on the frame contact pads, for example. Next, the remaining resisted is lifted off, followed by a plasma clean and inspection the frame chip, step 218.

As shown in FIG. 5, at step 220 a decision is made to determine if all conducting traces are completely formed. If not, process flow is directed to block 222 wherein steps 206 thru 218 can be repeated until all conducting traces are complete. Once all conducting traces have been developed, SEM imaging from the conducting traces to macrocontact pads can be performed, step 224, and a protective layer can be deposited over the device, step 226.

According to one embodiment, an SOI wafer was formed having an active silicon thickness of 192 nm, resistivity in the range of 9-15 ohm-cm, and a buried oxide thickness of 152.5 nm. In order to validate the ohmic contact procedure and the resistivity of the (non-milled) starting material, Ti/Al contacts may be applied using the Transfer Length Method (TLM) (i.e., thin parallel strips with predefined spacings and high length-to-spacing ratios (>5) to minimize stray fields). For the TLM test, the resistance may be measured as a function of electrode spacing and then plotted to determine the contact resistance of the device. It has been found that the contact resistance is approximately equal to the intercept on the resistance axis for a distance equal to zero. Based on this procedure, the contact resistance of an as-deposited ohmic contact on an as-received, non-milled wafer may approach 565 ohm, approximately. The average resistivity of the ohmic contact may be determined to be between 0.2 and 0.27 ohm/cm.

To demonstrate that the nanostructured 1D FET sensor of the present invention can be used to detect an environmental variable that may lead to corrosion, a Nafion layer is used as the sensor layer 30 (or sensitivity layer 52) and deposited over the top of the one dimensional channels 16 and then tested in a controlled humidity chamber, for example. The chamber may be as simple as a modified bell jar with a liquid reservoir and a rigid stage for mounting the sample and the micromanipulator armature for electrical contacts. A micromanipulator may be constructed for contacting the one dimensional FET in the controlled relative humidity chamber. Aqueous solutions, with specific saturated salt, may be used to establish the relative humidity.

Examples of some specific saturated solutions (salts) that may be used for verification purposes are listed in Table 1:

TABLE 1
Solution as a function of relative humidity

| | % Relative Air Humidity |
|---|---|
| Saturated Aqueous Solution | at 20° C. |
| Potassium Hydroxide (KOH) | 15 |
| Magnesium Chloride (MgCl) | 50.8 |
| Sodium Chloride (NaCl) | 71.2 |
| Sodium Carbonate (Na₂CO₃ 10H₂O) | 87.5 |
| Pure Water (H₂O) | 99.9 |

To determine the I-V response of a sensor, such as sensor 10, fabricated according to the invention for a specific Relative Humidity (RH), the specific saturated solution may first be placed in a reservoir in the bottom of the bell jar. The jar may then be sealed and allowed to equilibrate for approximately 1 to 2 hours. For RH levels above ˜80%, it has been observed that slight changes in the curves occur at the higher source-to-drain voltages (greater than 5 volts) for exposure times greater than 2 hours. To make the I-V measurement, the source-to-drain voltage of the device may be scanned from negative to positive voltages. The source-to-drain voltage was varied between (−) 8 and (+) 8 volts.

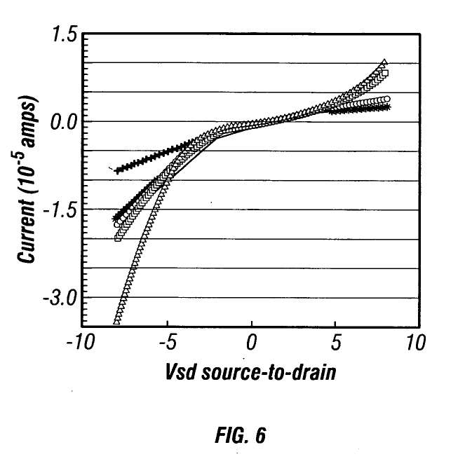

A typical I-V response curve as a function of specific relative humidity (in the closed bell jar) for a sensor according to one embodiment of the invention is shown in FIG. 6. As can be seen, there is a clear trend in the I-V response of the device as a function of relative humidity. Although +/−8 volts is used for the tests illustrated by FIG. 6, it may be sufficient to use less than a 5 volts bias. Therefore, the nanostructured FET sensor using a Nafion material as the sensor layer 30 according to the present invention has demonstrated the detection of the electrically based responses from several environments with a relative humidity from 15 to 100%. The novel sensing device has potential applications for monitoring atmospheric corrosion, either outdoor or indoor.

It should be understood that modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A one dimensional field effect transistor sensor comprising:
a doped silicon-on-insulator chip layer;
a plurality of nanostructured channels developed on said chip layer;
a sensor layer developed on said nanostructured channels, the sensor layer made of a material reactive to at least one environmental parameter of interest.

2. The sensor of claim 1 further comprising:
a first electrode coupled to a first end of said nanostructured channels;
a second electrode coupled to a second end of said nanostructured channels so that conductivity exists between said first and second electrodes via said nanostructured channels.

3. The sensor of claim 2 wherein said sensor layer comprises a Nafion material.

4. The sensor of claim 2 further comprising a protective coating layer developed over said nanostructured channels, said protective coating layer having an open area which allows some portion of said sensor layer to remain exposed to the environment.

5. The sensor of claim 4 further comprising:
at least one ohmic contact conductively coupled to either said first or second electrodes;
at least one macrocontact pad; and
a conducting trace conductively extending from said ohmic contact to said macrocontact pad to allow detection of signal changes between said first and second electrodes.

6. The sensor of claim 4 further comprising:
a plurality of ohmic contacts conductively coupled either said first or second electrodes;
a plurality of macrocontact pads; and
corresponding conducting traces providing conductive paths from either one of said first and second electrodes to a specific macrocontact pad allowing the detection of signal changes between said first and second electrodes.

7. The sensor of claim 2 wherein said nanostructured channels comprise 5 to 10 nanostructured channels, 50 to 100 nanometers in height and width and 0.8 to 2 microns in length.

8. A field effect transistor corrosion sensor comprising:
a doped silicon-on-insulator chip layer;
a plurality of nanostructured channels developed on said chip layer;
a Nafion receptive layer developed on said nanostructured channels;
a first electrode coupled to a first end of said nanostructured channels;
a second electrode coupled to a second end of said nanostructured channels so that signal conductivity is allowed between said first and second electrodes via said nanostructured channels.

9. The sensor of claim 8 further comprising a protective coating layer developed over said nanostructured channels, said protective coating layer having an open area which allows some portion of said Nafion receptive layer to remain exposed to the environment.

10. The sensor of claim 8 further comprising:
at least one ohmic contact conductively coupled to either said first or second electrodes;
at least one macrocontact pad; and
a conducting trace conductively extending from said ohmic contact to said macrocontact pad to allow detection of signal changes between said first and second electrodes.

11. The sensor of claim 8 wherein said nanostructured channels comprise 5 to 10 nanostructured channels, 50 to 100 nanometers in height and width and 0.8 to 2 microns in length.

12. A method of fabricating a field effect transistor corrosion sensor comprising the steps of:
constructing a frame chip layer to a nominal doped silicon thickness;
developing a plurality of nano-structured channels over said chip layer;
attaching electrode contact to ends of said channels;
placing a corrosion reactive sensitivity layer over said channels in between said electrodes; and
attaching a protective coating layer over said channels and said chip layer so that an open area exists over some portion of said sensitivity layer remains exposed to the environment.

13. The method of claim 12 wherein said step of constructing a frame chip layer includes using a boron-doped, p-type silicon-on-insulator semiconductor material.

14. The method of claim 12 wherein said step of placing a corrosion reactive sensitivity layer over said channels includes using a Nafion material as the sensitivity layer.

15. The method of claim 12 wherein said step of developing a plurality of nano-structured channels includes using standard electron beam lithography processes.

16. The method of claim 12 further comprising the step of depositing a SiO₂ insulation layer over said nanostructured channels.

17. The method of claim 12 wherein said step of developing a plurality of nano-structured channels includes using a polymethyl methacrylate resist.

18. The method of claim 12 further comprising the step of forming a set of ohmic contacts on said frame chip.

19. The method of claim 18 further comprising the steps of:
forming a set of corresponding macrocontacts pad;
forming conducting traces from said ohmic contacts to said macrocontact pads.

20. The method of claim 19 further comprising the step of metalizing said macrocontact pads.
